(19) United States
(12) Patent Application Publication
(10) Pub. No.: US 2015/0279452 A1
(43) Pub. Date: Oct. 1, 2015

(54) MEMORY HAVING A PULL-UP CIRCUIT WITH INPUTS OF MULTIPLE VOLTAGE DOMAINS

(71) Applicant: QUALCOMM Incorporated, San Diego, CA (US)

(72) Inventors: Sei Seung YOON, San Diego, CA (US); Derek Xiaoxiang Yang, Baldwin Park, CA (US); Alex Dongkyu Park, San Diego, CA (US); Venkatasubramanian Narayanan, San Diego, CA (US)

(73) Assignee: QUALCOMM Incorporated, San Diego, CA (US)

(21) Appl. No.: 14/228,091

(22) Filed: Mar. 27, 2014

(51) Int. Cl. G11C 11/419

(52) U.S. Cl. CPC G11C 11/419

(57) ABSTRACT

A memory and a method for operating the memory having a precharge circuit with inputs of multiple voltage domains are provided. In one aspect, a memory includes a bitline and one or more storage elements coupled to the bitline. The one or more storage elements are configured to operate in a first voltage domain using a first supply voltage. A pull-up circuit is configured to pull up the bitline to a second supply voltage in a second voltage domain. The pull-up circuit is responsive to a first control signal in the first voltage domain and a second control signal in the second voltage domain. The first supply voltage is different than the second supply voltage.

### BACKGROUND

1. Field

The present disclosure relates generally to electronic circuits, and more particularly, a memory having a pull-up circuit with inputs of multiple voltage domains.

2. Background

With the ever increasing demand for more processing capability in mobile devices, low power consumption has become a common design requirement. Various techniques are currently being employed to reduce power consumption in such devices. One such technique involves reducing the operating voltage of certain circuits in the device when certain operating conditions exist. As a result, different circuits may operate at different voltages. For example, in dual power rail memories, the storage elements and the peripheral logic may operate at different supply voltages. This may cause timing issues when the difference between the supply voltages is large. Accordingly, there is a need in the art for improved dual power rail memory circuits

### SUMMARY

Aspects of a memory are disclosed. The memory includes a memory includes a bitline and one or more storage elements coupled to the bitline. The one or more storage elements are configured to operate in a first voltage domain using a first supply voltage. A pull-up circuit is configured to pull up the bitline to a second supply voltage in a second voltage domain. The pull-up circuit is responsive to a first control signal in the first voltage domain and a second control signal in the second voltage domain. The first supply voltage is different than the second supply voltage.

Further aspects of a memory are disclosed. The memory includes a bitline and storage means for storing one or more values. The storage means is coupled to the bitline and is configured to operate in a first voltage domain using a first supply voltage. The memory further includes precharging means for pulling up the bitline to a to a second supply voltage in a second voltage domain. The precharging means is configured to receive a first control signal in the first voltage domain and a second control signal in the second voltage domain. The first supply voltage is different than the second supply voltage.

Aspects of a method for operating a memory are disclosed. The method includes operating one or more storage elements in a first voltage domain using a first supply voltage. The one or more storage elements are coupled to a bitline. The method further includes pulling up the bitline to a second supply voltage in a second voltage domain. The method further includes receiving, by a pull-up circuit, a first control signal in the first voltage domain and a second control signal in the second voltage domain. The method further includes disconnecting, by the pull-up circuit, the bitline from the second supply voltage in the second voltage domain based on at least one of the first control signal or the second control signal. The first supply voltage is different than the second supply voltage.

It is understood that other aspects of apparatus and methods will become readily apparent to those skilled in the art from the following detailed description, wherein various aspects of apparatus and methods are shown and described by way of illustration. As will be realized, these aspects may be implemented in other and different forms and its several details are capable of modification in various other respects. Accordingly, the drawings and detailed description are to be regarded as illustrative in nature and not as restrictive.

### BRIEF DESCRIPTION OF THE DRAWINGS

Various aspects of apparatus and methods will now be presented in the detailed description by way of example, and not by way of limitation, with reference to the accompanying drawings, wherein:

FIG. 1 is a block diagram illustrating an exemplary embodiment of a memory.

FIG. 2 is a block diagram illustrating an exemplary embodiment of a peripheral circuit supported by memory.

FIG. 3 is a schematic representation of an exemplary embodiment of a bitcell for an SRAM.

FIG. 4 is a functional block diagram of an exemplary embodiment of an SRAM.

FIG. 5 is a schematic diagram of various portions of an exemplary embodiment of a memory.

FIG. 6 is a functional block diagram of a control circuit for generating control signals in an exemplary embodiment of a memory.

FIG. 7 is a timing diagram of a read operation for an exemplary embodiment in the example that the memory operating voltage VDD_{MX} is higher than the peripheral circuit operating voltage VDD_{CX}.

FIG. 8 is a timing diagram of a read operation for an exemplary embodiment in the example that the peripheral circuit operating voltage VDD_{CX} is higher than the memory operating voltage VDD_{MX}.

FIG. 9 is a flowchart of the operation of an exemplary embodiment of a memory having a pull-up circuit with inputs of multiple voltage domains.

### DETAILED DESCRIPTION

The detailed description set forth below in connection with the appended drawings is intended as a description of various exemplary embodiments of the present invention and is not intended to represent the only embodiments in which the present invention may be practiced. The detailed description includes specific details for the purpose of providing a thorough understanding of the present invention. However, it will be apparent to those skilled in the art that the present invention may be practiced without these specific details. In some instances, well-known structures and components are shown in block diagram form in order to avoid obscuring the concepts of the present invention. Acronyms and other descriptive terminology may be used merely for convenience and clarity and are not intended to limit the scope of the invention.

Various apparatus and methods presented throughout this disclosure may be implemented in various forms of hardware. By way of example, any of these apparatus or methods, either alone or in combination, may be implemented as an integrated circuit, or as part of an integrated circuit. The integrated circuit may be an end product, such as a microprocessor, a digital signal processor (DSP), an application specific integrated circuit (ASIC), programmable logic, or any other suitable integrated circuit. Alternatively, the integrated circuit may be integrated with other chips, discrete circuit elements, and/or other components as part of either an intermediate product, such as a motherboard, or an end product. The end product can be any suitable product that includes integrated circuits, including by way of example, a cellular phone, personal digital assistant (PDA), laptop computer, a desktop computer (PC), a computer peripheral device, a multimedia device, a video device, an audio device, a global positioning system (GPS), a wireless sensor, or any other suitable device.

The word “exemplary” is used herein to mean serving as an example, instance, or illustration. Any embodiment described herein as “exemplary” is not necessarily to be construed as preferred or advantageous over other embodiments. Likewise, the term “embodiment” of an apparatus or method does not require that all embodiments of the invention include the described components, structure, features, functionality, processes, advantages, benefits, or modes of operation.

The terms “connected,” “coupled,” or any variant thereof, mean any connection or coupling, either direct or indirect, between two or more elements, and can encompass the presence of one or more intermediate elements between two elements that are “connected” or “coupled” together. The coupling or connection between the elements can be physical, logical, or a combination thereof. As used herein, two elements can be considered to be “connected” or “coupled” together by the use of one or more wires, cables and/or printed electrical connections, as well as by the use of electromagnetic energy, such as electromagnetic energy having wavelengths in the radio frequency region, the microwave region and the optical (both visible and invisible) region, as several non-limiting and non-exhaustive examples.

Any reference to an element herein using a designation such as “first,” “second,” and so forth does not generally limit the quantity or order of those elements. Rather, these designations are used herein as a convenient method of distinguishing between two or more elements or instances of an element. Thus, a reference to first and second elements does not mean that only two elements can be employed, or that the first element must precede the second element.

As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of the stated features, integers, steps, operations, elements, and/or components, but do not preclude the presence or addition of one or more other features, integers, steps, operations, elements, components, and/or groups thereof.

Various aspects of a memory on an integrated circuit (IC) using multiple voltage domains will now be presented. Such IC may be, for example, a system-on-chip (SOC) processor for a communication apparatus (such as a mobile phone). However, as those skilled in the art will readily appreciate, such aspects may be extended to other circuit configurations. Accordingly, all references to a specific application for a memory are intended only to illustrate exemplary aspects of the memory with the understanding that such aspects may be extended to a wide range of applications.

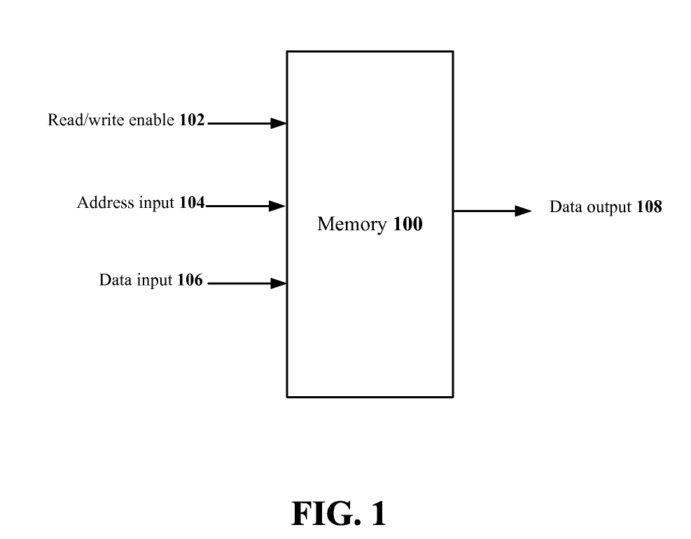

FIG. 1 is a block diagram illustrating an exemplary embodiment of a memory. The memory 100 provides a medium for peripheral circuits to write and read program instructions and data. As used hereinafter, the term “data” will be understood to include program instructions, data, and any other information that may be stored in the memory 100. The memory 100 includes a read/write enable 102 for controlling the read/write operation of the memory 100. The memory 100 also includes an address input 104, a data input 106 for writing date to the memory 100 at the specified address, and a data output 108 for reading data from the memory 100 at the specified address. When writing data to the memory 100, a peripheral circuit sets the read/write enable to the write mode and sends to the memory 100 the address along with the data to be written to the memory 102 at that address. When reading data from the memory 100, the peripheral circuit sets the read/write enable to the read mode and sends the address to the memory 100. In response, the memory 100 sends data at that address to the peripheral circuit.

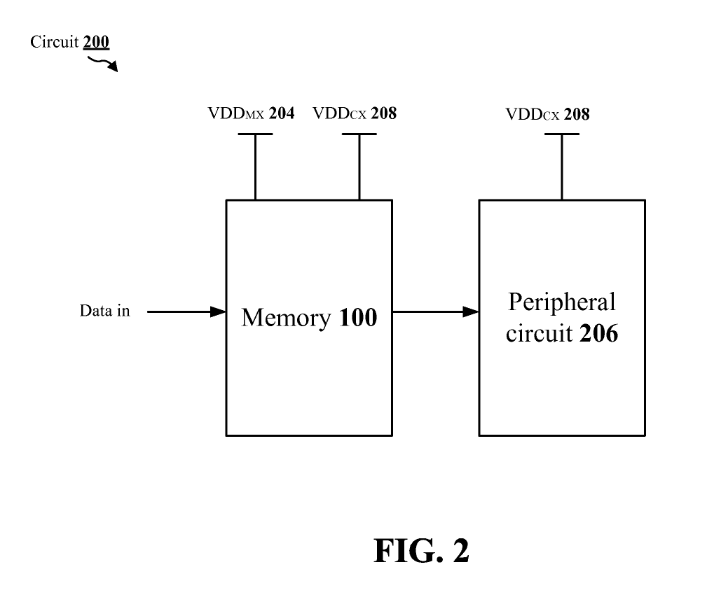

FIG. 2 is a block diagram illustrating an exemplary embodiment of a peripheral circuit supported by memory. The circuit 200 is shown with a memory 100 coupled to a first voltage rail (first supply voltage) VDD_{MX} 204 and a second voltage rail (second supply voltage) VDD_{CX} 208 and a peripheral circuit 206 coupled to the second voltage rail VDD_{CX} 208. In one example, the first supply voltage VDD_{MX} 204 may be the memory operating voltage, and the second supply voltage VDD_{CX} 208 may be the peripheral circuit operating voltage. Thus, the storage elements of the memory 100 operate in the VDD_{MX} domain using the supply voltage VDD_{MX}. The memory 100 is coupled to the peripheral circuit operating voltage VDD_{CX} (at 208) and is used, for example, by portions of memory 100 that interface with peripheral circuit 206. The peripheral circuit is to be construed broadly to include any suitable circuit that is peripheral to the memory 100 and capable of accessing the memory 100. In this example, the peripheral circuit 206 is shown reading data from the memory 100, however, as those skilled in the art will readily appreciate, the peripheral circuit 206 may also be capable of writing data to the memory 100.

As an example, the memory operating voltage VDD_{MX} (at 204) may be higher than the peripheral circuit operating voltage VDD_{CX} (at 208). In another example, the peripheral circuit operating voltage VDD_{CX} (at 208) may be higher than the memory operating voltage VDD_{MX} (at 204).

The memory 100 may be any suitable storage medium, such as, by way of example, a static random access memory (SRAM). SRAM is volatile memory that requires power to retain data. However, as those skilled in the art will readily appreciate, the memory 102 is not necessarily limited to SRAM. Accordingly, any reference to SRAM is intended only to illustrate various concepts, with the understanding that such concepts may be extended to other memories.

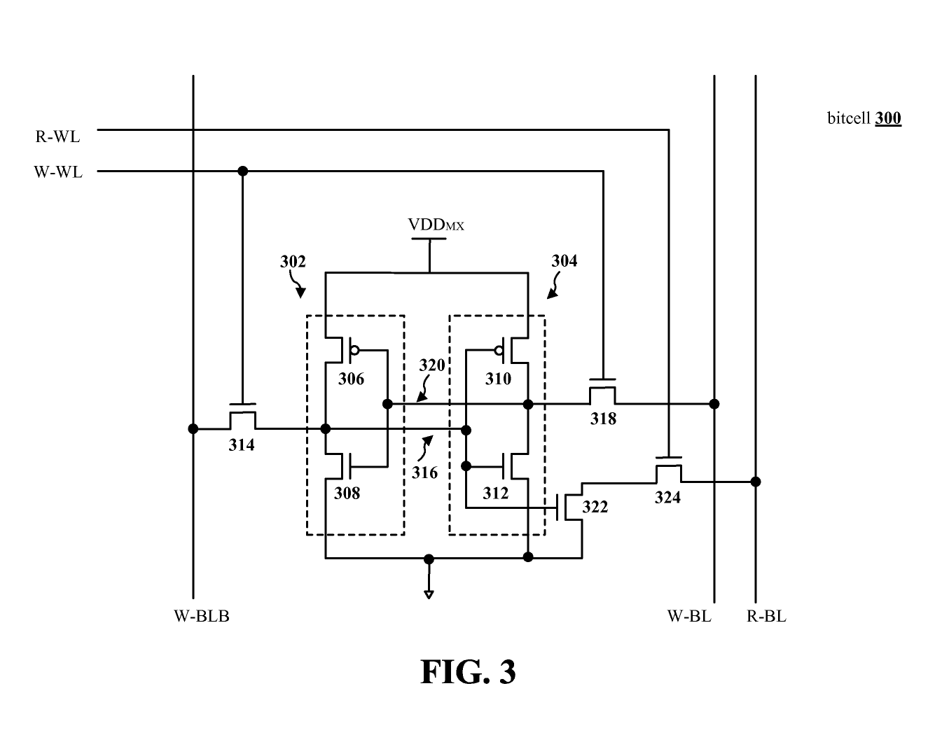

An SRAM includes an array of storage elements know as “bitcells.” Each bitcell is configured to store one bit of data. FIG. 3 is a schematic representation of an exemplary embodiment of a bitcell for an SRAM. The bitcell is implemented with an eight-transistor (8T) configuration. However, as those skilled in the art will readily appreciate, the bitcell may be implemented with a four-transistor (4T), six-transistor (6T), ten-transistor (10T) configuration, or any other suitable transistor configuration.

The bitcell 300 is shown with two inverters 302, 304. The first inverter 302 comprises a P-channel transistor 306 and an N-channel transistor 308. The second inverter 304 comprises a P-channel transistor 310 and an N-channel transistor 312. The first and second inverters 302, 304 are interconnected to form a cross-coupled latch. A first N-channel write access transistor 314 couples the output 316 from the first inverter 302 to a first local write bitline W-BLB and a second N-channel write access transistor 318 couples the output 320 from the second inverter 304 to a second local write bitline W-BL. The gates of the N-channel write access transistors 314, 318 are coupled to a write wordline W-WL. The output 316 from the first inverter 302 is also coupled to the gate of an N-channel transistor 322. An N-channel read access transistor 324 couples the output from the N-channel transistor 322 to a local read bitline R-BL. The gate of the N-channel read access transistor 324 is coupled to a read wordline R-WL.

The write operation is initiated by setting the local write bitlines W-BLB, W-BL to the value to be written to bitcell 300 and then asserting the write wordline W-WL. By way of example, a logic level 1 may be written to the bitcell 300 by setting the first local write bitline BLB to a logic level 0 and the second local write bitline BL to a logic level 1. The logic level 0 at the first local write bitline W-BLB is applied to the input of the second inverter 304 through the write access transistor 314, which in turn forces the output 320 of the second inverter 304 to a logic level 1. The output 320 of the second inverter 304 is applied to the input of the first inverter 302, which in turn forces the output 316 of the first inverter 302 to a logic level 0. A logic level 0 may be written to the bitcell 300 by inverting the values of the local write bitlines W-BLB, W-BL. The local write bitline drivers (not shown) are designed to be much stronger than the transistors in the bitcell 300 so that they can override the previous state of the cross-coupled inverters 302, 304.

The read operation is initiated by precharging the local read bitline R-BL to a logic level 1 and then asserting the read wordline R-WL. With the read wordline asserted, the output from the N-channel transistor 322 is transferred to the local read bitline R-BL through the read access transistor 324. By way of example, if the value stored at the output 320 of the second inverter 304 is a logic level 0, the output 316 from the first inverter 302 forces the N-channel transistor 322 on, which in turn causes the local read bitline R-BL to discharge to a logic level 0 through the read access transistor 324 and the N-channel transistor 322. If the value stored at the output 320 of the second inverter is a logic level 1, the output 316 from the first inverter 302 forces the N-channel transistor 322 off. As a result, the local read bitline R-BL remains charged to a logic level 1.

When the SRAM is in a standby mode, the write wordline W-WL and read wordline R-WL are set to a logic level 0. The logic level 0 causes the write access transistors 314, 318 and the read access transistor 324 to disconnect the local write and read bitlines W-BL, W-BLB, R-BL from the two inverters 302, 304. The cross-coupling between the two inverters 302, 304 maintains the state of the output as long as power is applied to the bitcell 300.

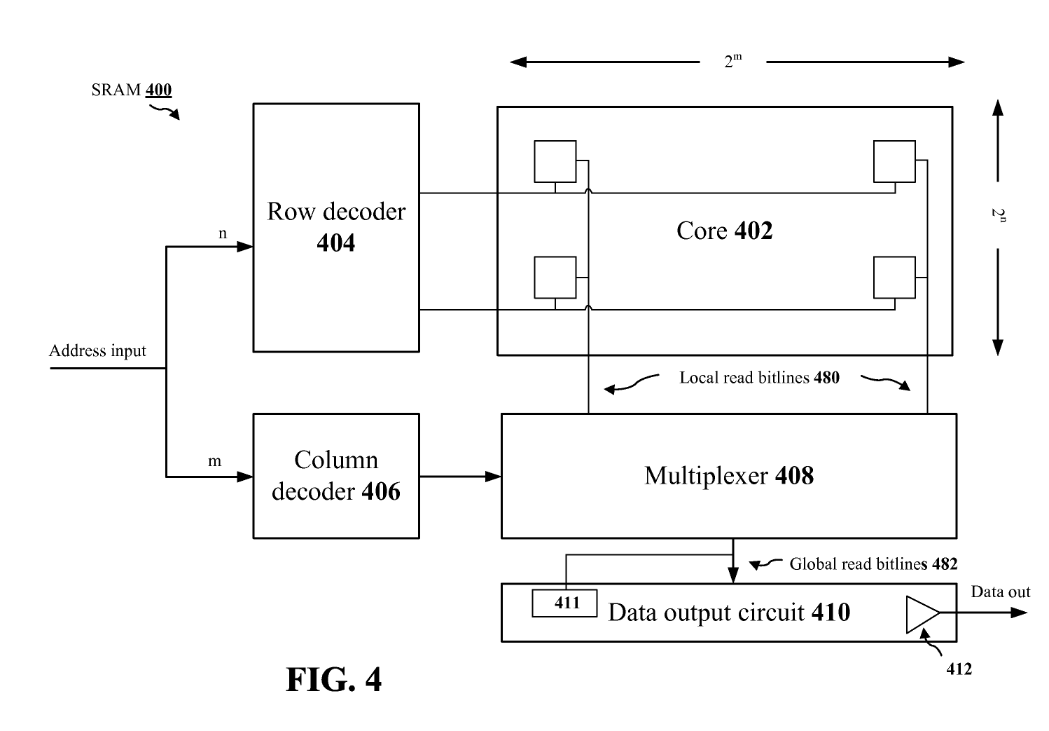

FIG. 4 is a functional block diagram of an exemplary embodiment of an SRAM. Various aspects of an SRAM will now be presented in the context of a read operation. Accordingly, for clarity of presentation, only the connections for the read operation are shown. Those skilled in the art will readily appreciate that additional connections are required to support the write operation.

The SRAM 400 includes a memory core 402 with supporting circuitry to decode addresses and perform read and write operations. The memory core 402 is comprised of bitcells arranged to share connections in horizontal rows and vertical columns. Specifically, each horizontal row of bitcells shares a read wordline and each vertical column of bitcells shares a local read bitline. The size of the memory core 402 (i.e., the number of bitcells) may vary depending on a variety of factors including the specific application, the speed requirements, the layout and testing requirements, and the overall design constraints imposed on the system. Typically, the memory core 402 will contain thousands or millions of bitcells.

In the exemplary embodiment of the SRAM shown in FIG. 4, the memory core 402 is made up of (2ⁿ×2^{m}) bitcells arranged in 2ⁿ horizontal rows and 2^{m} vertical columns. A peripheral device (not shown) may randomly access any bitcell in the memory core 402 using an address that is (n+m) bits wide. In this example, n-bits of the address are provided to the input of a row decoder 404 and m-bits of the address are provided to the input of a column decoder 406. The SRAM 400 is placed into a read mode by the read/write enable signal (not shown). The read/write enable signal causes, among other things, the precharging of the local read bitlines.

The row decoder 404 converts the n-bit address into 2ⁿ read wordline outputs. A different read wordline is asserted by the row decoder 404 for each different n-bit row address. As a result, each of the 2^{m} bitcells in the horizontal row with the asserted read wordline is connected to one of the 2^{m} local read bitlines 480 through its access transistor as described above in connection with FIG. 3. The 2^{m} local read bitlines 480 are used to transmit the bits stored by the 2^{m} bitcells to a multiplexer 408 that selects one or more bits from the 2^{m} bits transmitted on the local read bitlines 480. The number of bits that are selected by the multiplexer 408 is based on the width of the SRAM output. By way of example, the multiplexer 408 may select 64 of the 2^{m} bits to support an SRAM having a 64-bit output. In the described exemplary embodiment, the multiplexer 408 selects one of the 2^{m} bits. The selected bit may be referred to as a global read bitline 482. The global read bitline 482 output from the multiplexer 408 is provided to a data output circuit 410 for further processing before being output to a peripheral circuit (not shown). Thus, the global read bitlines 482 couples to bitcells (storage elements) via the local read bitlines 489. In one example, the data output circuit 410 provides the data from the global read bitline 482 to the peripheral circuit 206.

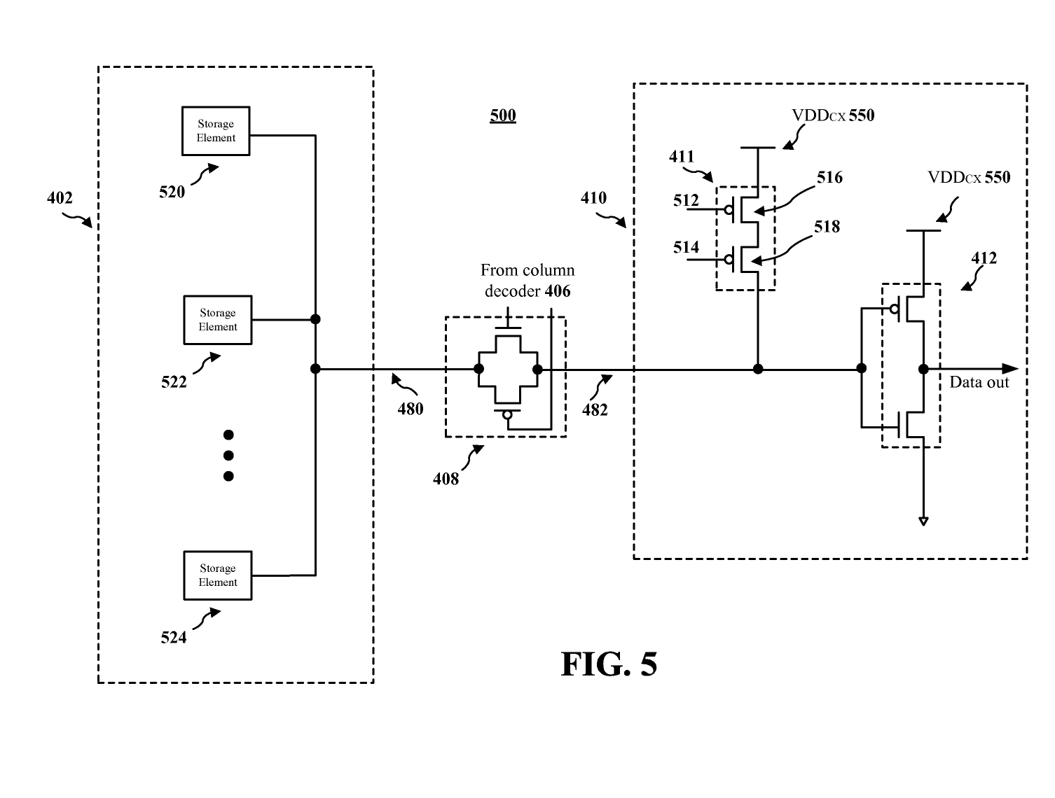

FIG. 5 is a schematic diagram illustrating various portions of an exemplary embodiment of a memory. In this example, the data output circuit 410 may include a driver circuit 412 for driving the data and a global read bitline pull-up circuit 411 for precharging the global read bitline 482. Prior to a read operation, the global read bitline pull-up circuit 411 may precharge or pull up the global read bitline 482 to the supply voltage VDD_{CX} in the VDD_{CX} voltage domain. In another example, the global read bitline pull-up circuit 411 may precharge or pull up the global read bitline 482 to the supply voltage VDD_{CX} in the VDD_{MX} voltage domain. After the precharge, a read operation may include the bitcell selectively pulling down or discharging the global read bitline 482 from the precharged level, based on the stored state of the bitcell.

In one example, the peripheral circuit operating voltage VDD_{CX} may be lower than the memory operating voltage VDD_{MX}. Due to the lower voltage, a control signal operating in the VDD_{CX} voltage domain for terminating the global read bitline 482 precharge may be generated later than necessary. In this case, the memory may take longer to turn off the global read bitline 482 precharge. The read operation, which starts after the precharge operation, may thus take longer than necessary to commence. One solution may be to speed up the generation of the control signal for terminating the global read bitline 482 precharge. However, in another case, the peripheral circuit operating voltage VDD_{CX} may be higher than the memory operating voltage VDD_{MX}. In this case, if the generation of the control signal for terminating the global read bitline 482 precharge is sped up, it may be too fast (i.e., terminating the global read bitline 482 precharge before the precharge is complete) due to the higher VDD_{CX} voltage. Accordingly, it may be advantageous for a memory to operate in both cases without having to change the design.

FIG. 5 illustrates that, in one example, the memory core 402 includes a plurality of storage elements 520, 522, 524, etc. coupled to the local read bitline 480. The storage elements may be examples of the memory bitcells with each bitcell providing a means for storing a value. A storage element may be, for example, an SRAM or other types of memory cell that stores a value (e.g., a value that may be read as a logic “1” or a logic “0”). The storage elements 520, 522, 524, etc. are coupled to the local read bitline 480. As described with FIG. 3, a memory bitcell 300 may include an N-channel transistor 322 which functions as a pull-down circuit to the local read bitline 480 in a read operation.

In one exemplary embodiment, the storage elements 520, 522, 524, etc. in the memory may operate at operating voltage VDD_{MX} as described in greater detail above in connection with FIG. 3. For example, the storage elements 520, 522, 524, etc. may be written, read, or otherwise operated in the VDD_{MX} voltage domain.

In one exemplary embodiment, the local read bitline 480 may be coupled to the global read bitline 482 via a multiplexer 408, as described with FIG. 4. In this example, the multiplexer 408 is illustrated as a pass gate. As would be understood by one of ordinary skill in the art, the multiplexer 408 could be implemented using various circuits. One additional example of multiplexer 408 is a selective pull-down circuit having the local read bitline 480 providing an input to a pull-down circuit of the global read bitline 482.

The global read bitline pull-up circuit 411 may be couple to VDD_{CX} (at 550). In this example, the global read bitline pull-up circuit 411 is configured to precharge the global read bitline 482 to the peripheral circuit operating voltage VDD_{CX}. The global read bitline pull-up circuit 411 provides a means to precharge or pull up the global read bitline 482.

For a read access of the memory core 402, an initial operation may include the global read bitline pull-up circuit 411 precharging (pulling up) the global read bitline 482 to VDD_{CX}. Subsequent to the precharge operation, during a read operation, the multiplexer 408 either pulls the global read bitline 482 low or allows the global read bitline 482 to remain high from the precharge operation based on the stored value of the selected storage element (520, 522, or 524, etc.). Specifically, the multiplexer 408 controls the voltage of the global read bitline 482 based on the voltage of the local read bitline 480.

In one exemplary embodiment, the global read bitline pull-up circuit 411 may receive the control signals 512 and 514 operating in different voltage domains for disconnecting the global read bitline 482 from VDD_{CX} at 550. For example, the control signal 512 may operate in the VDD voltage domain, and the control signal 514 may operate in the VDD_{CX} voltage domain. In this example, the global read bitline pull-up circuit 411 may include a p-type metal-oxide-semiconductor (PMOS) transistor 516 having a gate coupled to the control signal 512 and a PMOS transistor 518 having a gate coupled to the control signal 514. The two PMOS transistors 516 and 518 may be connected in series (i.e., may be stacked) between VDD_{CX} (at 550) and the global read bitline 482. As would be understood by one skilled in the art, in such configuration, the global read bitline pull-up circuit 411 precharges the global read bitline 482 to VDD_{CX} in response to both the control signals 512 and 514 being in a low state. When one of the control signals 512 and 514 goes high, the global read bitline pull-up circuit 411 is disabled, and VDD_{CX} (at 550) is disconnected from the global read bitline 482. Thus, the global read bitline pull-up circuit 411 receives control signals 512 and 514 to determine whether to disconnect VDD_{CX} (at 550) from the global read bitline 482.

In other words, the global read bitline pull-up circuit 411 may be responsive to the control signal 512 in the VDD voltage domain and responsive to the control signal 514 in the VDD_{CX} voltage domain. The global read bitline pull-up circuit 411 may disconnect the global read bitline 482 from the supply voltage VDD_{CX} in the VDD_{CX} voltage domain is response to the control signal 512 in the VDD_{MX} voltage domain going high. Likewise, the global read bitline pull-up circuit 411 may disconnect the global read bitline 482 from the supply voltage VDD_{CX} in the VDD_{CX} voltage domain is response to the control signal 514 in the VDD_{CX} voltage domain going high.

In the described exemplary embodiment, the global read bitline 482 is coupled to the driver circuit 412 operating at VDD_{CX}. In this example, the global read bitline 482 is connected to the input of the driver circuit 412. The driver circuit 412 may provide the value of the read operation to circuits outside of the memory that operate in the VDD_{CX} voltage domain. In this example, the memory illustrated in FIG. 5 may be an embedded memory on an integrated circuit (IC), and the driver circuit 412 provides the value of the read operation to other blocks of the IC.

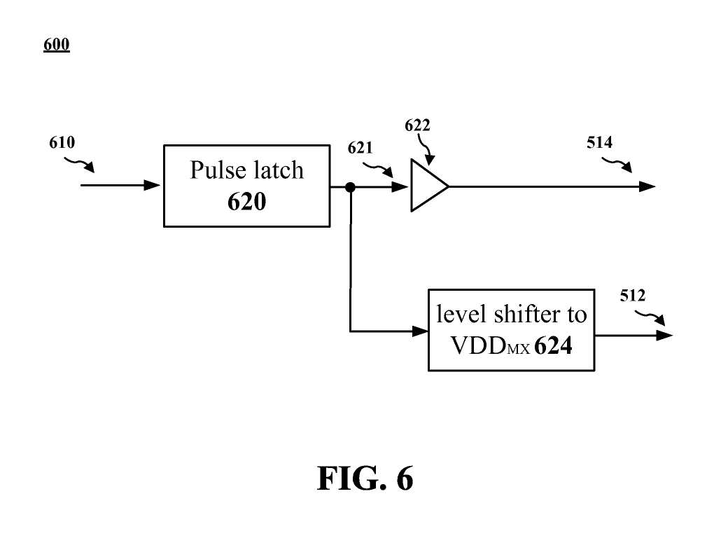

FIG. 6 illustrates a control circuit for generating control signals in an exemplary embodiment of a memory. The control circuit 600 may generate the control signal 512 operating in the VDD_{MX} voltage domain, and the control signal 514 operating in the VDD_{CX} voltage domain. In one example, the control signal 512 may range in value from a ground level to the supply voltage VDD_{MX}. The control signal 514 may range in value from the ground level to the supply voltage VDD_{CX}.

The control circuit 600 includes a pulse latch 620 that latches a signaling event of the master clock signal 610. For example, the master clock signal 610 may be a clock which initiates the memory operation. The captured signaling event may be, for example, the master clock signal 610 going high. The pulse latch 620 may latch the signaling event of the master clock signal 610 and generate an output 621 of a predetermined period, in accordance with the knowledge of one skilled in the art. The output 621 of the pulse latch is provided to a driver 622, which outputs the control signal 514. In this example, the master clock signal 610, pulse latch 620, output 621, driver 622, and control signal 514 may all be in the VDD_{CX} voltage domain.

The output 621 is also provided to a level shifter 624, which shifts the output 621 to the VDD_{MX} voltage domain. The level shifter 624 outputs the control signal 512 in the VDD_{MX} voltage domain. In one example, the memory operating voltage VDD_{MX} is higher than the peripheral circuit operating voltage VDD_{CX}. As a result, the control signal 512 operating in the memory operating voltage VDD_{MX} may be generated faster than the control signal 514 operating in the peripheral circuit operating voltage VDD_{CX}. In another example, the peripheral circuit operating voltage VDD_{CX} is higher than the memory operating voltage VDD_{MX}. As a result, the control signal 514 operating in the peripheral circuit operating voltage VDD_{CX} may be generated faster than the control signal 512 operating in the memory operating voltage VDD_{MX}.

Accordingly, both the control signals 512 and 514 may be triggered off a same signaling event (e.g., the master clock signal 610 going high). In the example, the control circuit 600 provides a means for generating the control signals 512 and 514 from a signaling event. The control signals 512 and 514 are provided to the global read bitline pull-up circuit 411. In response to the triggering of either the control signal 512 or the control signal 514, the global read bitline pull-up circuit 411 may disconnect VDD_{CX} (at 550) from the global read bitline 482.

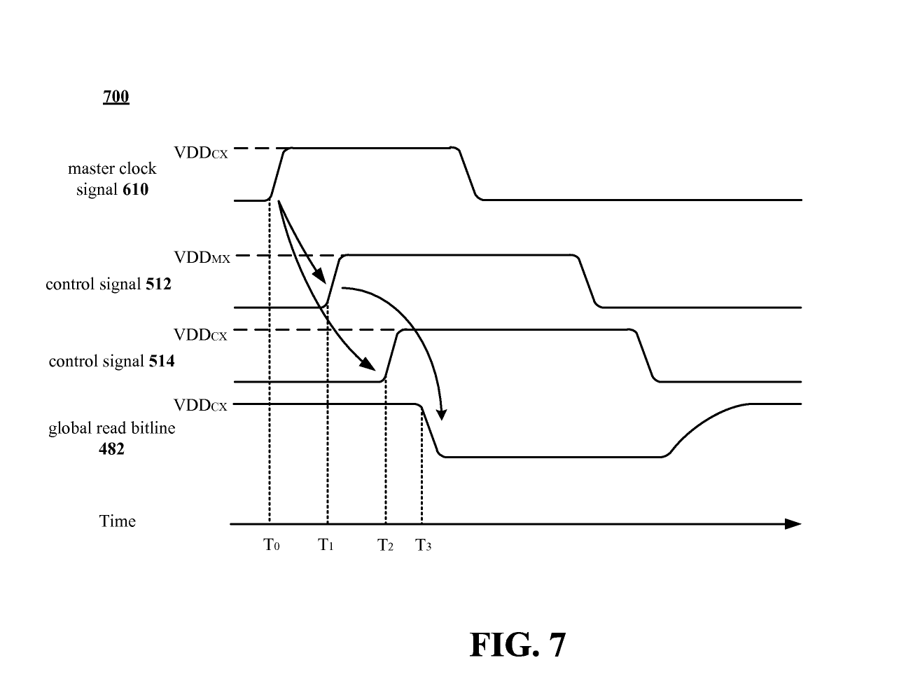

FIG. 7 is a timing diagram 700 of a read operation for an exemplary embodiment in the example that the memory operating voltage VDD_{MX} is higher than the peripheral circuit operating voltage VDD_{CX}. Initially, both the control signals 512 and 514 are at a low level (e.g., the ground level). The global read bitline pull-up circuit 411 is enabled and charges the global read bitline 482 to VDD_{CX}. At T₀, a signaling event is triggered (e.g., the master clock signal 610 goes high). The signaling event initiates a read access for the memory. In response, the control signals 512 and 514 go high to disable the global read bitline pull-up circuit 411. In this example, the control signal 512 operating in the higher VDD voltage domain is generated faster than the control signal 514 operating in the VDD_{CX} voltage domain. At T₁, the control signal 512 rises to VDD in response to the signaling event at T₀. As a result, the global read bitline pull-up circuit 411 is disabled, and VDD_{CX} (at 550) is disconnected from the global read bitline 482. A read operation may initiate after T₁, regardless of the state of the control signal 514. At a later time T₂, the control signal 514 rises to VDD_{CX} in response to the signaling event at T₀. At T₃, as a result of the read operation initiated after the control signal 512 rising to VDD_{MX}, the global read bitline 482 is pull low. For example, a selected storage element (520, 522, or 524, etc.) pulls down the local read bitline 480 (and therefore, the global read bitline 482 coupled thereto) based on its stored value.

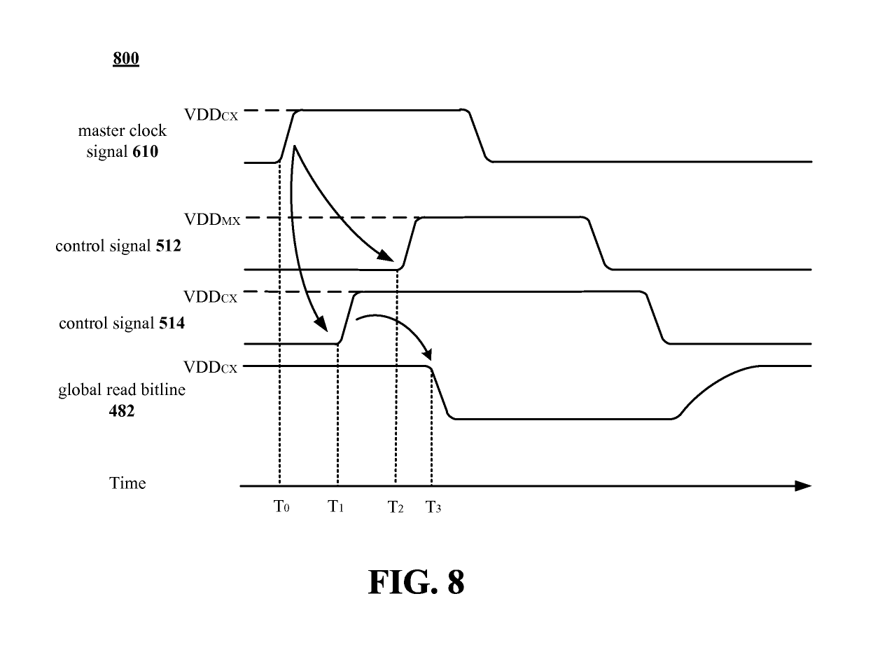

FIG. 8 is a timing diagram 800 of a read operation for an exemplary embodiment in the example that the peripheral circuit operating voltage VDD_{CX} is higher than the memory operating voltage VDD_{MX}. Initially, both the control signals 512 and 514 are at a low level (e.g., the ground level). The global read bitline pull-up circuit 411 is enabled and charges the global read bitline 482 to VDD_{CX}. At T₀, a signaling event is triggered (e.g., the master clock signal 610 goes high). The signaling event initiates a read access for the memory. In response, the control signals 512 and 514 go high to disable the global read bitline pull-up circuit 411. In this example, the control signal 514 operating in the higher VDD_{CX} voltage domain is generated faster than the control signal 512 operating in the VDD_{MX} voltage domain. At T₁, the control signal 514 rises to VDD_{CX} in response to the signaling event at T₀. As a result, the global read bitline pull-up circuit 411 is disabled, and VDD_{CX} at 550 is disconnected from the global read bitline 482. A read operation may initiate after T₁, regardless of the state of the control signal 512. At a later time T₂, the control signal 512 rises to VDD_{MX} in response to the signaling event at T₀. At T₃, as a result of the read operation initiated after the control signal 514 rising to VDD_{CX}, the global read bitline 482 is pull low. For example, a selected storage element (520, 522, or 524, etc.) pulls down the local read bitline 480 (and therefore, the global read bitline 482 coupled thereto) based on its stored value.

As described above, in the example that the memory operating voltage VDD_{MX} is higher than the peripheral circuit operating voltage VDD_{CX} (FIG. 7), the read operation may be timed off the faster control signal 512 (operating in the higher VDD_{MX} voltage domain) going high. Similarly, in the example that the peripheral circuit operating voltage VDD_{CX} is higher than the memory operating voltage VDD_{MX} (FIG. 8), the read operation may be timed off the faster control signal 514 (operating in the higher VDD_{CX} voltage domain) going high. In this fashion, the described circuits (e.g., FIG. 5) may operate in both cases without modification.

Although the exemplary embodiment and the operations thereof described above are directed at a global read bitline 482, the embodiment and features are not necessarily limited thereto. As one of ordinary skill in the art would recognize, the described embodiment and features would be applicable to bitlines in general (e.g., global bitlines and local bitlines). Further, the global bitlines may be coupled to local bitlines via various circuits, which are not limited to the multiplexer described above.

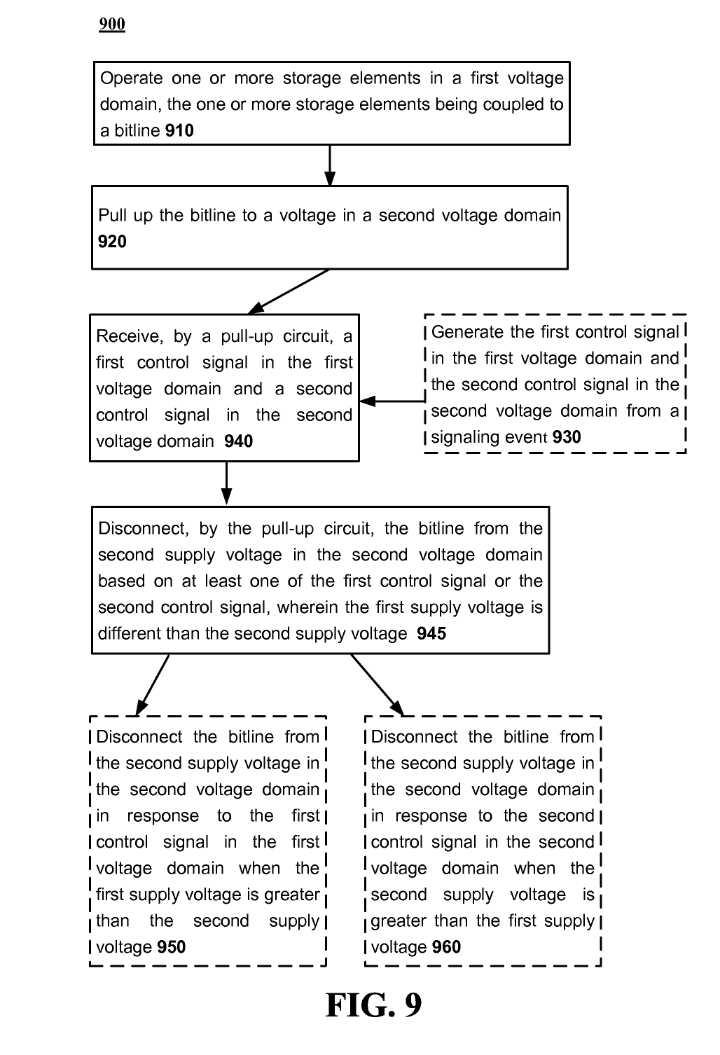

FIG. 9 is the flowchart of the operations of a memory having a precharge circuit with inputs of multiple voltage domains. The steps illustrated in dotted lines may be optional. At 910, one or more storage elements coupled to a bitline (e.g., the global read bitline 482) operate in a first voltage domain (e.g., the VDD_{MX} voltage domain). At 920, the bitline is pulled up to a voltage in a second voltage domain (e.g., the VDD_{CX} voltage domain). At 930, the first control signal (e.g., the control signal 512) in the first voltage domain and the second control signal (e.g., the control signal 514) in the second domain are generated from a signaling event (e.g., the master clock signal 610 going high). At 940, a pull-up circuit receives the first control signal in the first voltage domain and the second control signal in the second voltage domain. At 945, the pull-up circuit disconnects the bitline from the second supply voltage in the second voltage domain based on at least one of the first control signal or the second control signal (see FIG. 7 and FIG. 8). The first supply voltage is different than the second supply voltage. At 950, in one example, the bitline is disconnected from the second supply voltage in the second voltage domain in response to the first control signal in the first voltage domain when the first supply voltage is greater than the second supply voltage (see FIG. 7). At 960, in another example, the bitline is disconnected from the second supply voltage in the second voltage domain in response to the second control signal in the second voltage domain when the second supply voltage is greater than the first supply voltage (see FIG. 8). Examples of these operations are described in association with FIGS. 5-8.

The specific order or hierarchy of blocks in the method of operation described above is provided merely as an example. Based upon design preferences, the specific order or hierarchy of blocks in the method of operation may be re-arranged, amended, and/or modified. The accompanying method claims include various limitations related to a method of operation, but the recited limitations are not meant to be limited in any way by the specific order or hierarchy unless expressly stated in the claims.

The various aspects of this disclosure are provided to enable one of ordinary skill in the art to practice the present invention. Various modifications to exemplary embodiments presented throughout this disclosure will be readily apparent to those skilled in the art, and the concepts disclosed herein may be extended to other magnetic storage devices. Thus, the claims are not intended to be limited to the various aspects of this disclosure, but are to be accorded the full scope consistent with the language of the claims. All structural and functional equivalents to the various components of the exemplary embodiments described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112(f) unless the element is expressly recited using the phrase “means for” or, in the case of a method claim, the element is recited using the phrase “step for.”

What is claimed is:

1. A memory, comprising:
a bitline;
one or more storage elements coupled to the bitline, the one or more storage elements being configured to operate in a first voltage domain using a first supply voltage; and
a pull-up circuit configured to pull up the bitline to a second supply voltage in a second voltage domain, wherein the pull-up circuit is responsive to a first control signal in the first voltage domain and a second control signal in the second voltage domain, the first supply voltage being different than the second supply voltage.

2. The memory of claim 1, wherein the pull-up circuit is further configured to disconnect the bitline from the second supply voltage in the second voltage domain in response to the first control signal in the first voltage domain.

3. The memory of claim 1, wherein the pull-up circuit is further configured to disconnect the bitline from the second supply voltage in the second voltage domain in response to the second control signal in the second voltage domain.

4. The memory of claim 1, wherein the pull-up circuit comprises a first transistor and a second transistor connected in series between the second supply voltage and the bitline.

5. The memory of claim 4, wherein the first transistor is configured to be controlled by the first control signal in the first voltage domain, and the second transistor is configured to be controlled by the second control signal in the second voltage domain.

6. The memory of claim 5, further comprising a control circuit configured to generate the first control signal and the second control signal from a signaling event.

7. The memory of claim 1, wherein the first control signal ranges in value from a ground level to the first supply voltage and the second control signal ranges in value from the ground level to the second supply voltage.

8. The memory of claim 1, further comprising a control circuit configured to generate the first control signal before the second control signal when the first supply voltage is greater than the second supply voltage, and to generate the second control signal before the first control signal when the second supply voltage is greater than the first supply voltage.

9. The memory of claim 1, wherein the bitline comprises a global bitline.

10. A method of operating a memory, comprising:
operating one or more storage elements in a first voltage domain using a first supply voltage, the one or more storage elements being coupled to a bitline;
pulling up the bitline to a second supply voltage in a second voltage domain;
receiving, by a pull-up circuit, a first control signal in the first voltage domain and a second control signal in the second voltage domain; and
disconnecting, by the pull-up circuit, the bitline from the second supply voltage in the second voltage domain based on at least one of the first control signal or the second control signal, wherein the first supply voltage is different than the second supply voltage.

11. The method of claim 10, further comprising disconnecting the bitline from the second supply voltage in the second voltage domain in response to the first control signal in the first voltage domain when the first supply voltage is greater than the second supply voltage.

12. The method of claim 10, further comprising disconnecting the bitline from the second supply voltage in the second voltage domain in response to the second control signal in the second voltage domain when the second supply voltage is greater than the first supply voltage.

13. The method of claim 12, further comprising generating the first control signal in the first voltage domain and the second control signal in the second voltage domain from a signaling event.

14. A memory, comprising:
a bitline;
storage means for storing one or more values, wherein the storage means is coupled to the bitline and is configured to operate in a first voltage domain using a first supply voltage; and
precharging means for pulling up the bitline to a to a second supply voltage in a second voltage domain, wherein the precharging means is configured to receive a first control signal in the first voltage domain and a second control signal in the second voltage domain, the first supply voltage being different than the second supply voltage.

15. The memory of claim 14, wherein the precharging means is further configured to disconnect the bitline from the second supply voltage in the second voltage domain in response to the first control signal in the first voltage domain.

16. The memory of claim 14, wherein the precharging means is further configured to disconnect the bitline from the second supply voltage in the second voltage domain in response to the second control signal in the second voltage domain.

17. The memory of claim 16, wherein the precharging means comprises a first transistor and a second transistor connected in series between the second supply voltage and the bitline.

18. The memory of claim 17, wherein the first transistor is configured to be controlled by the first control signal in the first voltage domain, and the second transistor is configured to be controlled by the second control signal in the second voltage domain.

19. The memory of claim 14, further comprising control signal generating means for generating the first control signal and the second control signal from a signaling event.

20. The memory of claim 14, wherein the bitline comprises a global bitline.
